(19) United States
(12) Patent Application Publication
(10) Pub. No.: US 2025/0248243 A1
(43) Pub. Date: Jul. 31, 2025

(54) DISPLAY SUBSTRATE AND DISPLAY DEVICE

(71) Applicants: Beijing BOE Technology Development Co., Ltd., Beijing (CN); BOE Technology Group Co., Ltd., Beijing (CN)

(72) Inventors: Jingjing XU, Beijing (CN); Dacheng ZHANG, Beijing (CN); Pan LI, Beijing (CN); Chen XU, Beijing (CN); Yong QIAO, Beijing (CN); Jingquan WANG, Beijing (CN); Xinyin WU, Beijing (CN)

(21) Appl. No.: 18/693,967

(22) PCT Filed: Jul. 19, 2023
(86) PCT No.: PCT/CN2023/108154

§ 371 Date: Mar. 21, 2024

(30) Foreign Application Priority Data
Mar. 21, 2023 (CN) 202310279509.3

(51) Int. Cl. H10K 59/131; H10K 59/122; H10K 59/80; H10K 102/00

(52) U.S. Cl. CPC H10K 59/131; H10K 59/122; H10K 59/8731; H10K 2102/351

(57) ABSTRACT

A display substrate and a display device are provided. The display substrate includes a drive structure layer (131) and a light emitting structure layer that are stacked sequentially on a base substrate (121); the light emitting structure layer includes an anode layer, a pixel definition layer (171), a light emitting functional layer (181) and a cathode layer (191) that are disposed sequentially in a direction away from the base substrate (121); the anode layer includes multiple anodes (24), the pixel definition layer (171) is disposed on a side of the multiple anodes (24) facing away from the base substrate (121) and is provided with multiple pixel openings (172), the pixel openings (172) expose the anodes (24), the light emitting functional layer (181) and the cathode layer (191) are stacked sequentially on a side of the anodes (24) facing away from the base substrate (121).

### CROSS-REFERENCE TO RELATED APPLICATIONS

The present application is a U.S. National Phase Entry of International Application No. PCT/CN2023/108154 having an international filing date of Jul. 19, 2023, which claims priority to Chinese patent application No. 202310279509.3, filed to CNIPA on Mar. 21, 2023 and entitled “Display Substrate and Display Device”. The entire contents of the above-identified applications are hereby incorporated by reference.

### TECHNICAL FIELD

Embodiments of the present disclosure relate to, but are not limited to, the field of display technologies, and particularly relate to a display substrate and a display device.

### BACKGROUND

In order to improve brightness of some organic light emitting diodes (OLED) display panels, the light emitting elements adopt a tandem structure, but a charge generation layer (CGL) contained in this structure may generate moving charges under an action of voltage. Because of a large transverse conductivity of the charge generation layer and a close distance between sub-pixels, it may cause leakage between sub-pixels and cause cross-color problems among sub-pixels.

### SUMMARY

The following is a summary of subject matters described herein in detail. This summary is not intended to limit the protection scope of the claims.

In a first aspect, an embodiment of the present disclosure provides a display substrate including multiple sub-pixels disposed on a base substrate. The multiple sub-pixels include a first sub-pixel emitting a first color light, a second sub-pixel emitting a second color light, and a third sub-pixel emitting a third color light. The sub-pixels each include a light emitting element. The display substrate includes a drive structure layer and a light emitting structure layer that are stacked sequentially on the base substrate. The light emitting structure layer includes an anode layer, a pixel definition layer, a light emitting functional layer and a cathode layer sequentially disposed in a direction away from the base substrate. The anode layer includes multiple anodes, the pixel definition layer is disposed on a side of the multiple anodes facing away from the base substrate and is provided with multiple pixel openings, the pixel openings expose the anodes, and the light emitting functional layer and the cathode layer are stacked sequentially on the side of the anodes facing away from the base substrate. The pixel openings define the sub-pixels, and the light emitting element includes the anodes, the light emitting functional layer and the cathode layer. The display substrate further includes a partition structure. The partition structure includes a groove located between adjacent anodes and a protrusion located between adjacent pixel openings.

In a second aspect, an embodiment of the present disclosure provides a display device including the display substrate in the aforementioned embodiment.

Other features and advantages of the present disclosure will be set forth in the following specification, and partially become apparent from the specification, or are understood by implementing the present disclosure. Other advantages of the present disclosure may be achieved and obtained through solutions described in the specification and drawings.

Other aspects of the present disclosure may be comprehended after the drawings and the detailed description are read and understood.

### BRIEF DESCRIPTION OF DRAWINGS

The drawings are intended to provide further understanding of technical solutions of the present disclosure and form a part of the specification, and are used to explain the technical solutions of the present disclosure together with embodiments of the present disclosure, but do not form limitations on the technical solutions of the present disclosure. Shapes and sizes of components in the drawings do not reflect actual scales, and are only intended to schematically illustrate contents of the present disclosure.

FIG. 1 is a schematic diagram of a partial planar structure of a display area of a display substrate according to an exemplary embodiment of the present disclosure;

FIG. 2 is a schematic diagram of another partial planar structure of a display area of a display substrate according to an exemplary embodiment of the present disclosure;

FIG. 3 is a schematic view of a sectional structure taken along a cutting line C in FIG. 1 or FIG. 2;

FIG. 4 is a schematic diagram of a partial structure of FIG. 3;

FIG. 5 is a schematic top view of a partial structure of a display substrate according to an exemplary embodiment of the present disclosure;

FIG. 6 is a schematic diagram of another partial structure of FIG. 3;

FIG. 7 is a schematic diagram of yet another partial structure of FIG. 3;

FIG. 8 is a schematic sectional view of a partial structure of a display substrate according to an exemplary embodiment of the present disclosure;

FIG. 9 is a schematic top view of another partial structure of a display substrate according to an exemplary embodiment of the present disclosure;

FIG. 10 is a schematic sectional view of another partial structure of a display substrate according to an exemplary embodiment of the present disclosure; and

FIG. 11 is a schematic diagram of a partial planar structure of a display substrate according to an exemplary embodiment of the present disclosure.

### DETAILED DESCRIPTION

Those of ordinary skills in the art should understand that modifications or equivalent replacements may be made to technical solutions of embodiments of the present disclosure without departing from the spirit and scope of the technical solutions of the embodiments of the present disclosure, and should all fall within the scope of the claims of the present disclosure.

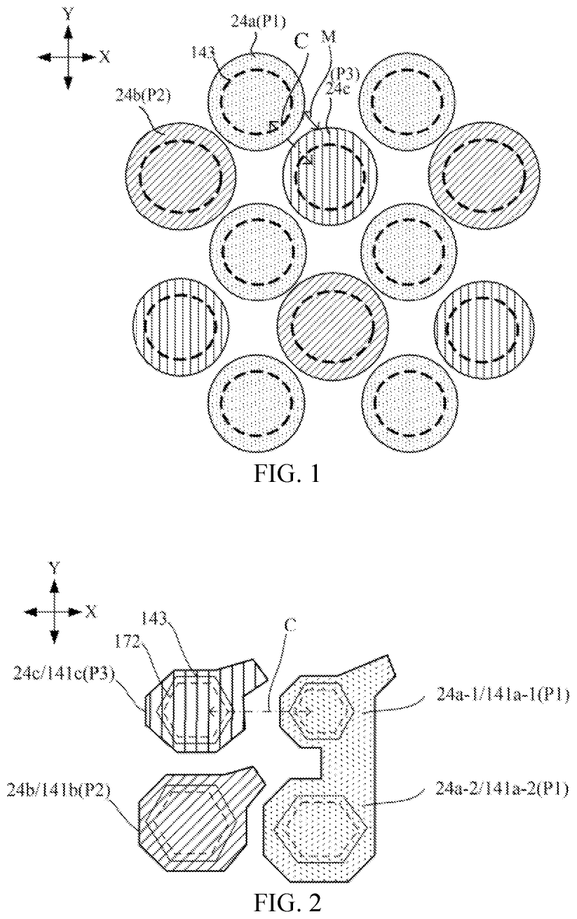

FIG. 1 is a schematic diagram of a partial planar structure of a display area of a display substrate according to an exemplary embodiment of the present disclosure. As shown in FIG. 1, the display area of the display substrate may include multiple sub-pixels disposed on a base substrate, and the multiple sub-pixels may include a first sub-pixel P1 emitting a first color light, a second sub-pixel P2 emitting a second color light, and a third sub-pixel P3 emitting a third color light. One pixel unit may include three sub-pixels, i.e. one pixel unit may include one first sub-pixel P1, one second sub-pixel P2, and one third sub-pixel P3. Alternatively, one pixel unit may include four sub-pixels, i.e. one pixel unit may include two first sub-pixels P1, one second sub-pixel P2, and one third sub-pixel P3. In an example, the first sub-pixel P1 may emit green light, the second sub-pixel P2 may emit blue light, and the third sub-pixel P3 may emit red light. In the present disclosure, sub-pixels emitting light of different colors may be referred to as sub-pixels of different colors or different kinds of sub-pixels.

In some exemplary embodiments, as shown in FIG. 1, multiple sub-pixels of the display area may be arranged into multiple pixel rows extending in a first direction X and multiple pixel columns extending in a second direction Y. In an example, the multiple sub-pixels may be arranged into multiple first pixel rows, multiple second pixel rows, multiple first pixel columns, and multiple second pixel columns. A second sub-pixel P2 and a third sub-pixel P3 are alternately disposed in the first direction X to form a first pixel row, multiple first sub-pixels P1 are disposed sequentially in the first direction X to form a second pixel row, the first pixel row and the second pixel row are alternately disposed in the second direction Y, and sub-pixels of two adjacent pixel rows are disposed in a staggered manner. A second sub-pixel P2 and a third sub-pixel P3 are alternately disposed in the second direction Y to form a first pixel column, multiple first sub-pixels P1 are disposed sequentially in the second direction Y to form a second pixel column, the first pixel column and the second pixel column are alternately disposed in the first direction X, and sub-pixels of two adjacent pixel columns are disposed in a staggered manner. In other exemplary implementations, a type and arrangement of the multiple sub-pixels of the display area may be provided in other manners, and embodiments of the present disclosure are not limited to the type and arrangement of the multiple sub-pixels of the display area herein. In an exemplary embodiment, the first direction X intersects with the second direction Y. For example, the first direction X may be an extension direction (horizontal row direction) of scan signal lines in a display panel, and the second direction Y may be an extension direction (vertical column direction) of data signal lines in the display panel. The first direction X and the second direction Y may be perpendicular to each other.

In an example, each sub-pixel may include one light emitting element, and the light emitting element may be an OLED (Organic Light Emitting Diode) or a QLED (Quantum-dot Light Emitting Diode) device. The present disclosure does not limit a light emitting color of the light emitting element of the sub-pixel. For example, the light emitting element may emit white light, and light of a set color is emitted from the sub-pixel in cooperation with a color filter layer (i.e., a color film layer), or the light emitting color of the light emitting element of the sub-pixel may be the same as the color of the light emitted from the sub-pixel.

In some exemplary embodiments, the light emitting element may include an anode, a light emitting functional layer, and a cathode layer that are stacked sequentially along a direction away from the base substrate. The light emitting functional layer may include an organic emitting layer, may also include any one or more film layers of a hole injection layer, a hole transport layer, and an electron block layer between the anode and the organic emitting layer, and may also include any one or more film layers of an electron injection layer, an electron transport layer, and a hole block layer between the cathode layer and the organic emitting layer. The light emitting functional layer may include one organic emitting layer. Alternatively, the light emitting functional layer may include multiple organic emitting layers and one or more charge generation layers, and the organic emitting layers and the charge generation layer(s) are disposed alternately in the direction away from the base substrate to form a tandem light emitting structure. The tandem light emitting structure is helpful to improve light emitting brightness of the display substrate and reduce power consumption. However, a charge generation layer in the tandem light emitting structure is generally a common layer, that is, the charge generation layers of multiple sub-pixels are of an integral structure, and the charge generation layers are continuous between adjacent sub-pixels. Because of a large transverse conductivity of the charge generation layers, it is easy to cause leakage between sub-pixels and cause cross-color problems among sub-pixels.

In some exemplary embodiments, the display substrate may further include a pixel definition layer, the pixel definition layer is provided with multiple pixel openings, a light emitting element is provided at the pixel opening, and one pixel opening defines one sub-pixel. In the present disclosure, a sub-pixel area can be understood as an effective light emitting area of the sub-pixel (i.e. the area defined by the pixel opening of the sub-pixel).

In some exemplary embodiments, a partition structure may also be provided on the display substrate. The partition structure is configured to partition at least one common layer (such as a charge generation layer) in the light emitting functional layer, so that the at least one common layer (such as a charge generation layer) in the light emitting functional layer is disconnected between adjacent sub-pixels.

In some exemplary embodiments, as shown in FIG. 1, anodes 24 of the multiple sub-pixels are illustrated in FIG. 1, including an anode 24a of a first sub-pixel P1, an anode 24b of a second sub-pixel P2, and an anode 24c of a third sub-pixel P3. The partition structure may include a groove (not shown) and a protrusion 143. The groove is provided in an area between adjacent anodes 24. For example, an area indicated by a straight line M with an arrow in FIG. 1 may represent an area between an anode 24a of the first sub-pixel P1 and an anode 24c of the adjacent third sub-pixel P3.

In some exemplary embodiments, as shown in FIG. 1, the protrusion 143 is provided in an area between pixel openings of adjacent sub-pixels. A shape of the protrusion 143 may be substantially the same or at least partially the same as a shape of the anode 24. For example, when the anode 24 is circular or substantially circular, the protrusion 143 may be circular, substantially circular or at least partially arc-shaped, and when the anode 24 is a polygon formed by straight sides, the protrusion 143 may be a polygon formed by straight sides or at least partially have straight sides. Such a setting facilitates process stability. When the anode 24 is an octagonal shape with a nearly circular outer contour, the protrusion 143 may be circular or at least partially arc-shaped. Such a setting can simplify a process while ensuring process stability.

The groove and the protrusion may refer to a structure with a protrusion or a depression in a direction perpendicular to the base substrate.

In some exemplary embodiments, the anode may include a first anode and a second anode that are disposed sequentially in a direction away from the base substrate, an insulation layer may be disposed between the first anode and the second anode, and the second anode is connected to the first anode through a first via provided in the insulation layer. For example, in the example of FIG. 1, the anode of each sub-pixel may be understood as the first anode of each sub-pixel.

FIG. 2 is a schematic diagram of another partial planar structure of a display area of a display substrate according to an exemplary embodiment of the present disclosure. FIG. 2 illustrates another pixel arrangement structure. As shown in FIG. 2, the display area of the display substrate may include multiple pixel units arranged in an array on a base substrate (FIG. 2 illustrates one pixel unit), and one pixel unit may include four sub-pixels, such as two first sub-pixels P1, one second sub-pixel P2, and one third sub-pixel P3. Four sub-pixels in a pixel unit may be arranged in two rows and two columns and are substantially rectangular, the two first sub-pixels P1 are located in the same column, and the second sub-pixel P2 and the third sub-pixel P3 are located in the same column. Herein, a row direction is a first direction X in FIG. 2 and a column direction is a second direction Y in FIG. 2. That is, in the pixel unit, one of the first sub-pixels P1 and the third sub-pixel P3 are located in the same row and arranged along the first direction X, the other of the first sub-pixels P1 and the second sub-pixel P2 are located in the same row and arranged along the first direction X, the two first sub-pixels P1 are located in the same column and arranged along the second direction Y, and the second sub-pixel P2 and the third sub-pixel P3 are located in the same column and arranged along the second direction Y. The first direction X intersects with the second direction Y, for example, the first direction X and the second direction Y may be perpendicular to each other.

In an example, a light emission wavelength of the second sub-pixel P2 is smaller than a light emission wavelength of the first sub-pixel P1 and a light emission wavelength of the first sub-pixel P1 is smaller than a light emission wavelength of the third sub-pixel P3. For example, the first sub-pixel P1 may emit green light, the second sub-pixel P2 may emit blue light, and the third sub-pixel P3 may emit red light.

In some exemplary embodiments, as shown in FIG. 2, each sub-pixel of the display area may have a size smaller than 10 microns in a direction parallel to the base substrate. A total area of the two anodes 24a-1 and 24a-2 of the two first sub-pixels P1 in one pixel unit may be greater than an area of the anode 24b of the second sub-pixel P2, and the area of the anode 24b of the second sub-pixel P2 may be greater than an area of the anode 24c of the third sub-pixel P3.

In an example, as shown in FIG. 2, the two anodes 24a-1 and 24a-2 of the two first sub-pixels P1 in the pixel unit may be connected to be of an integral structure. The two anodes 24a-1 and 24a-2 of the two first sub-pixels P1 may have an equal potential. Sizes of pixel openings 172 of the two first sub-pixels P1 in the pixel unit may be equal or unequal. This structure is helpful to adjust a hue of a full-color display. Here, “A and B may be connected to be of an integral structure” as described in the present disclosure may mean that A and B are connected to each other and A is a part of B, or A and B may be arranged in the same layer of the same material and A and B may be made by a single patterning process.

In some other exemplary embodiments, the anode may include a first anode and a second anode that are disposed sequentially in a direction away from the base substrate. An insulation layer may be disposed between the first anode and the second anode, and the second anode is connected to the first anode through a first via provided in the insulation layer.

In an example, as shown in FIG. 2, the first anode 141a of the first sub-pixel P1, the first anode 141b of the second sub-pixel P2, and the first anode 141c of the third sub-pixel P3 are illustrated in FIG. 2. In the pixel unit, the two first anodes 141a-1 and 141a-2 of the two first sub-pixels P1 may be connected to be of an integral structure, or the two second anodes of the two first sub-pixels P1 may be connected to be of an integral structure. Alternatively, the two first anodes 141a-1 and 141a-2 of the two first sub-pixels P1 may be connected to be of an integral structure, and the two second anodes of the two first sub-pixels P1 may be connected to be of an integral structure. The anodes of the two first sub-pixels P1 may have an equal potential.

In an example, as shown in FIG. 2, in one pixel unit, a total area of the two first anodes 141a-1 and 141a-2 of the two first sub-pixels P1 may be greater than an area of the first anode 141b of the second sub-pixel P2, and the area of the first anode 141b of the second sub-pixel P2 may be greater than an area of the first anode 141c of the third sub-pixel P3.

In an example, as shown in FIG. 2, in the pixel unit, an area of a pixel opening 172 of the second sub-pixel P2 is greater than an area of a pixel opening 172 of the third sub-pixel P3, and the area of the pixel opening 172 of the third sub-pixel P3 is greater than an area of the pixel opening 172 of any one of the first sub-pixels P1 and less than a sum of the areas of the pixel openings 172 of the two first sub-pixels P1 in one pixel unit.

In an example, as shown in FIG. 2, a protrusion 143 is provided on a periphery of the pixel opening 172 of the sub-pixel of at least one color in the direction parallel to the base substrate. For example, a protrusion 143 may be provided only on the periphery of the pixel opening 172 of the sub-pixel of one color, or a protrusion 143 may be provided on the periphery of the pixel opening 172 of the sub-pixel of each color. Here, illustration is made in FIG. 2 by taking a case in which a protrusion 143 is provided on the periphery of the pixel opening 172 of each sub-pixel in the pixel unit as an example.

In some exemplary embodiments, the protrusion 143 may surround at least one sub-pixel. A shape of the protrusion 143 is not limited and a quantity of protrusions 143 surrounding at least one sub-pixel is not limited. For example, one sub-pixel may be surrounded by one closed or unclosed annular protrusion 143 or one sub-pixel may be surrounded by multiple protrusions 143 provided at intervals. The shape of the protrusion 143 may be an annular, a straight line, a bending line, a curve, or the like.

In some exemplary embodiments, as shown in FIG. 2, an orthographic projection of the anode 24 of at least one sub-pixel on the base substrate may include an orthographic projection of the pixel opening 172 of the sub-pixel on the base substrate, and may include an orthographic projection of the protrusion 143 surrounding the sub-pixel on the base substrate. In an example, the shape of the anode 24 may be substantially octagonal, the shape of the protrusion 143 may be substantially hexagonal, and both the shape of the anode 24 and the shape of the protrusion 143 are nearly circular.

In some other exemplary embodiments, the anode may include a first anode and a second anode that are disposed sequentially in a direction away from the base substrate, an insulation layer may be disposed between the first anode and the second anode, and the second anode is connected to the first anode through a first via provided in the insulation layer.

In an example, as shown in FIG. 2, the first anode 141a of the first sub-pixel P1, the first anode 141b of the second sub-pixel P2, and the first anode 141c of the third sub-pixel P3 are illustrated in FIG. 2. An orthographic projection of the first anode 141 of at least one sub-pixel on the base substrate includes an orthographic projection of the pixel opening 172 of the sub-pixel on the base substrate, and may include an orthographic projection of the protrusion 143 surrounding the sub-pixel on the base substrate. In an example, a shape of the first anode 141 may be substantially octagonal, the shape of the protrusion 143 may be substantially hexagonal, and both the shape of the first anode 141 and the shape of the protrusion 143 are nearly circular. In other implementations, in the direction parallel to the base substrate, the protrusion 143 may be provided close to an edge of the first anode 141 and substantially identical to a contour shape of the first anode 141.

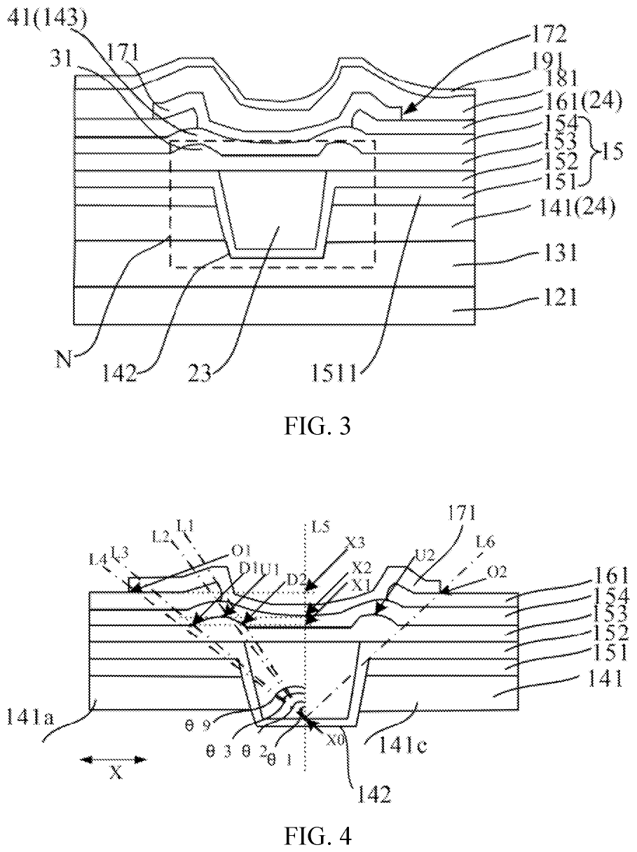

FIG. 3 is a schematic view of a sectional structure taken along a cutting line C in FIG. 1 or FIG. 2. As shown in FIG. 3, in a direction perpendicular to the base substrate 121, the display substrate may include a drive structure layer 131 and a light emitting structure layer that are stacked sequentially on the base substrate 121. The light emitting structure layer may include an anode layer, a pixel definition layer 171, a light emitting functional layer 181, and a cathode layer 191 that are disposed sequentially in a direction away from the base substrate 121.

In some exemplary embodiments, the anode layer may include multiple anodes 24, and the pixel definition layer 171 is disposed on a side of the multiple anodes 24 facing away from the base substrate 121 and provided with multiple pixel openings 172. The pixel openings 172 expose the anodes 24, and the light emitting functional layer 181 and the cathode layer 191 are stacked sequentially on a side of the anodes 24 facing away from the base substrate 121. The pixel openings 172 define the sub-pixels and the light emitting element may include the anodes 24, the light emitting functional layer 181, and the cathode layer 191.

In some exemplary embodiments, the display substrate may also include a partition structure. The partition structure may include a groove 142 located between adjacent anodes 24 and a protrusion 143 between adjacent pixel openings 172, and at least one film layer of the light emitting functional layer 181 is disconnected at a position corresponding to the partition structure.

In an embodiment of the present disclosure, by providing the partition structure which includes the groove 142 and the protrusion 143, at least one film layer (such as a charge generation layer) in the light emitting functional layer 181 can be disconnected at a position corresponding to the partition structure (an area indicated by a dashed line box N), thereby preventing cross-color problems between sub-pixels caused by the charge generation layer being continuous between adjacent sub-pixels.

In some exemplary embodiments, as shown in FIG. 3, the anode layer may include a first anode layer and a second anode layer that are disposed sequentially in the direction away from the base substrate 121, and the light emitting structure layer may also include an insulation layer 15 disposed between the first anode layer and the second anode layer.

The first anode layer includes multiple first anodes 141, the second anode layer includes multiple second anodes 161, and the second anodes 161 are connected with the first anodes 141 through a first via provided in the insulation layer 15. The anodes 24 include the first anode 141 and the second anode 161 connected through the first via, the pixel definition layer 171 is disposed on a side of the multiple second anodes 161 and the insulation layer 15 facing away from the base substrate 121, and the pixel openings 172 expose the second anode 161. The light emitting functional layer 181 and the cathode layer 191 are stacked sequentially on a side of the second anode 161 facing away from the base substrate 121.

The groove 142 is provided on a surface of the drive structure layer 131 facing away from the base substrate 121, and the protrusion 143 is provided on a surface of the insulation layer 15 facing away from the base substrate 121. In the direction parallel to the base substrate 121, the grooves 142 are located between adjacent first anodes 141 and the protrusion 143 is located between adjacent pixel openings 172.

In an embodiment of the present disclosure, the anodes include a first anode 141 and a second anode 161 electrically connected, and an insulation layer 15 is disposed between the first anode 141 and the second anode 161, and a protrusion 143 is provided on a surface of the insulation layer 15 facing away from the base substrate 121. In this way, in some implementations, a micro-cavity structure (emitted light of the light emitting element can be enhanced by the micro-cavity structure) can be formed between the first anode 141 and the cathode layer 191, and a cavity length of the micro-cavity structure can be adjusted by adjusting a thickness of the insulation layer 15, so that light emitting wavelength bands of different sub-pixels may be adjusted, thereby optimizing the full-color display effect of the display substrate.

In some exemplary embodiments, the drive structure layer 131 may include multiple pixel drive circuits and multiple signal lines (including a gate line, a data line, a power supply line and the like). The pixel drive circuits may include multiple transistors (T) and a storage capacitor (C), for example, the pixel drive circuits may have a structure, such as, 3T1C, 7T1C, etc. The embodiment of the present disclosure is not limited to the structure of the pixel drive circuits. In some implementations, the display substrate may be a silicon based micro organic emitting diode (micro OLED) display substrate and the pixel drive circuits may be fabricated using a complementary metal oxide semiconductor (CMOS) integrated circuit process. The pixel drive circuits are connected to the first anode 141 of the light emitting element and configured to drive the light emitting element to emit light.

In some exemplary embodiments, as shown in FIG. 3, the groove 142 may also be located between adjacent protrusions 143 in the direction parallel to the base substrate 121, which may enhance the partition effect of the partition structure on the charge generation layer and reduce the possibility of cross-color between adjacent sub-pixels.

In some exemplary embodiments, as shown in FIG. 3, an orthographic projection of the protrusion 143 on the base substrate 121 may be overlapped with an orthographic projection of the first anode 141 on the base substrate 121.

In some exemplary embodiments, as shown in FIG. 3, thicknesses of the insulation layers 15 of the sub-pixels of different colors may be different, so that the cavity lengths of the micro-cavity structures of the sub-pixels of different colors may be different, thereby optimizing the light emitting wavelength bands of different sub-pixels, and thereby further optimizing the full-color display effect of the display substrate. Among the sub-pixels of different colors, the longer the light emitting wavelength of the sub-pixel, the greater the thickness of the insulation layer of the sub-pixel may be.

In some exemplary embodiments, as shown in FIG. 3, the insulation layer 15 may include multiple film layers that are stacked, and at least one film layer of the insulation layer 15 is discontinuous between pixel openings 172 of the sub-pixels of different colors. Thus, it is possible to adjust the thicknesses of the insulation layer 15 of the sub-pixels of different colors by adjusting the thicknesses of the discontinuous film layers between the pixel openings 172 of the sub-pixels of different colors in the insulation layer 15 in the sub-pixels of different colors, thereby realizing the adjustment of the cavity length of the micro-cavity structure of the sub-pixels of different colors.

In some exemplary embodiments, as shown in FIG. 3, the insulation layer 15 may include multiple film layers that are stacked, and at least one film layer of the insulation layer 15 close to the base substrate is discontinuous between the pixel openings 172 of the sub-pixels of different colors and not disposed within the groove 142. At least one film layer of the insulation layer 15 away from the base substrate is continuous between the pixel openings 172 of the sub-pixels of different colors.

In an example, a film layer in the insulation layer 15 close to the base substrate 121 may include multiple insulation sub-layers 1511, each insulation sub-layer 1511 is disposed on a side of a corresponding first anode 141 facing away from the base substrate 121, and an orthographic projection of the first anode 141 on the base substrate 121 may include an orthographic projection of the insulation sub-layer 1511 on the base substrate 121. The thicknesses of the insulation sub-layers 1511 of the sub-pixels of different colors may be different and the micro-cavity lengths of the sub-pixels of different colors may be adjusted by adjusting the thicknesses of the insulation sub-layers 1511 of the sub-pixels of different colors.

In some exemplary embodiments, as shown in FIG. 3, the insulation layer 15 may include multiple film layers that are stacked. The light emitting structure layer may also include a filling layer 23 disposed within the groove 142, and a film layer located on a side of the filling layer 23 facing away from the base substrate 121 in the insulation layer 15 is provided with the protrusions 143.

In an example, as shown in FIG. 3, the insulation layer 15 may include a first insulation layer 151, a second insulation layer 152, a third insulation layer 153, and a fourth insulation layer 154 that are stacked sequentially in the direction away from the base substrate 121, and a second anode 161 is disposed on a surface of the fourth insulation layer 154 facing away from the base substrate 121. The first insulation layer 151 may include multiple insulation sub-layers 1511, each insulation sub-layer 1511 is disposed on a side of a corresponding first anode 141 facing away from the base substrate 121, and the orthographic projection of the first anode 141 on the base substrate 121 includes the orthographic projection of the insulation sub-layer 1511 on the base substrate 121. The second insulation layer 152, the third insulation layer 153, and the fourth insulation layer 154 may all be continuous between pixel openings 172 of sub-pixels of different colors. The second insulation layer 152, the third insulation layer 153, and the fourth insulation layer 154 may all be full-face structures. Thus, on one hand, it is possible to adjust the cavity length of the micro-cavity structure of the sub-pixels of different colors by adjusting the thickness of the insulation sub-layer 1511 in the sub-pixels of different colors, and on the other hand, it is possible to adjust the cavity length of the micro-cavity structure of the sub-pixels of different colors by adjusting local thicknesses of the second insulation layer 152, the third insulation layer 153 and the fourth insulation layer 154. The second insulation layer 152 may be disposed on a surface of the multiple insulation sub-layers 1511 facing away from the base substrate 121, and may be disposed on peripheral sidewalls of the multiple insulation sub-layers 1511 and the multiple first anodes 141, and may be disposed on a groove wall of the groove 142. The second insulation layer 152 may include a first part on a surface of the insulation sub-layer 1511 facing away from the base substrate 121 (a planarization part on a side of the first anode 141 facing away from the base substrate 121), a third part on a bottom wall of the groove 142, and a second part (a slop part on peripheral sidewalls of the insulation sub-layer 1511, the first anode 141, and the groove 142) connecting the first part and the third part. The second part and the third part of the second insulation layer 152 are recessed toward a side close to the base substrate 121 compared to the first part and form a recessed part. The filling layer 23 may be disposed on a surface of the second insulation layer 152 facing away from the base substrate 121 and within the recessed part of the second insulation layer 152. The third insulation layer 153 is disposed on surfaces of the second insulation layer 152 and the filling layer 23 facing away from the base substrate 121, and a first protrusion 31 is formed on the third insulation layer 153 at a position corresponding to a connective position between the first part and the second part of the second insulation layer 152. The third insulation layer 153 may include a fourth part (planarization part), located on a first part of the second insulation layer 152 and in contact with the first protrusion 31; a sixth part, located on the filling layer 23 and in contact with the first protrusion 31; and the first protrusion (fifth part) 31, connecting the fourth part and the sixth part. The fourth insulation layer 154 is disposed on a surface of the third insulation layer 153 facing away from the base substrate 121, a second protrusion 41 is formed correspondingly on the fourth insulation layer 154 at a position corresponding to the first protrusion 31 of the third insulation layer 15, and the second protrusion 41 may serve as a protrusion 143 of the partition structure. In some other exemplary implementations, the insulation layer 15 may include a second insulation layer 152 and a third insulation layer 153 that are stacked sequentially in the direction away from the base substrate 121, that is, the first insulation layer 151 and the fourth insulation layer 154 may not be disposed, the second anode 161 may be disposed on a surface of the third insulation layer 153 facing away from the base substrate 121, and the first protrusion 31 on the third insulation layer 153 is the protrusion of the partition structure.

In some exemplary embodiments, as shown in FIG. 3, total thicknesses of the second insulation layer 152 and the third insulation layer 153 of the sub-pixels of different colors may be different. For example, the first sub-pixel may emit green light, the second sub-pixel may emit blue light, and the third sub-pixel may emit red light. A ratio of a total thickness of the second insulation layer 152 and the third insulation layer 153 of the first sub-pixel to a total thickness of the second insulation layer 152 and the third insulation layer 153 of the third sub-pixel may be 1:1.1. Thus micro-cavity lengths of the sub-pixels of different colors may be adjusted by adjusting the total thicknesses of the second insulation layer 152 and the third insulation layer 153 of the sub-pixels of different colors. For example, among sub-pixels of different colors, the longer the light emitting wavelength of the sub-pixel, the greater the total thickness of the second insulation layer 152 and the third insulation layer 153 of the sub-pixel may be.

In some exemplary embodiments, as shown in FIG. 3, thicknesses of the fourth insulation layers 154 of the sub-pixels of different colors may be different, or the thicknesses of the insulation sub-layers 1511 of the sub-pixels of different colors may be different, or the thicknesses of the fourth insulation layers 154 and the thicknesses of the insulation sub-layers 1511 of the sub-pixels of different colors may be different. Thus, the micro-cavity lengths of the sub-pixels of different colors may be adjusted by adjusting the thicknesses of the fourth insulation layers 154 or/and the insulation sub-layers 1511 of the sub-pixels of different colors. For example, among sub-pixels of different colors, the longer the light emitting wavelength of the sub-pixel, the greater the thickness of at least one of the fourth insulation layer 154 and the insulation sub-layer 1511 of the sub-pixel may be.

In some exemplary embodiments, as shown in FIG. 3, the second anode 161 is disposed on a surface of the insulation layer 15 facing away from the base substrate 121 and a part of the second anode 161 close to the edge is located on the protrusion 143.

In some exemplary embodiments, as shown in FIG. 3, an orthographic projection of the pixel definition layer 171 on the base substrate 121 may include an orthographic projection of the protrusion 143 on the base substrate 121, such that a surface of the part of the second anode 161 exposed by the pixel opening 172 may be ensured to be planar, improving the optical display effect.

In some exemplary embodiments, as shown in FIG. 3, a material of the pixel definition layer 171 may be an inorganic material. For example, a material of the pixel definition layer 171 may include silicon nitride, silicon oxide and the like.

In some exemplary embodiments, as shown in FIG. 3, a material of the insulation layer 15 may be an inorganic material. For example, a material of the insulation layer 15 may include at least one of silicon nitride, silicon oxide, and silicon oxynitride. In an example, a material of the first insulation layer 151 and the fourth insulation layer 154 may be silicon oxide, a refractive index of the first insulation layer 151 and the fourth insulation layer 154 may be about 1.46, a material of the second insulation layers 152 and the third insulation layer 153 may be silicon nitride, and a refractive index of the second insulation layers 152 and the third insulation layer 153 may be about 1.8.

In some exemplary embodiments, as shown in FIG. 3, the first anode 141 may have better reflectivity and may be a metal layer. The first anode 141 may be made of a single metal material, or may be made of an alloy material, such as titanium aluminum alloy (Ti/Al), aluminum copper alloy (Al/Cu) or titanium aluminum silver alloy (Ti/Al/Ag). The first anode 141 may be a single-layer structure or may be a laminated structure of multiple metal layers. A material of the cathode layer 191 may be a magnesium silver alloy (Mg/Ag). A micro-cavity structure may be formed between the first anode 141 and the cathode layer 191, which may enhance the light emitted from the light emitting element.

In some exemplary embodiments, the partition structure partitions at least one film layer in the light emitting functional layer 181 and may or may not partition the cathode layer 191. That is, the cathode layer 191 may be disconnected or continuous at a position corresponding to the partition structure.

In some exemplary embodiments, FIG. 4 is a schematic diagram of a partial structure of FIG. 3. As shown in FIG. 4, multiple sub-pixels of the display area may include a first reference sub-pixel and a second reference sub-pixel that are adjacent (for example, a left sub-pixel is the first reference sub-pixel and a right sub-pixel is the second reference sub-pixel in FIG. 4). A groove between the first anode of the first reference sub-pixel and the first anode of the second reference sub-pixel is used as a first reference groove, a first protrusion provided on the third insulation layer 153 at the periphery of the pixel opening of the first reference sub-pixel is used as a first reference protrusion, and a first protrusion provided on the third insulation layer 153 at the periphery of the pixel opening of the second reference sub-pixel is used as a second reference protrusion. A section parallel to an arrangement direction of the first reference sub-pixel and the second reference sub-pixel and perpendicular to the base substrate is taken as a first reference plane (section of an example in FIG. 4). The arrangement direction of the first reference sub-pixel and the second reference sub-pixel is an extension direction of a line connecting a center of the effective light emitting area of the first reference sub-pixel and a center of the effective light emitting area of the second reference sub-pixel (a first direction X in an example of FIG. 4). Here, an extension direction of a line connecting the centers of effective light emitting areas (an area defined by a pixel opening of a sub-pixel) of adjacent sub-pixels is taken as an arrangement direction of the adjacent sub-pixels.

In some exemplary embodiments, as shown in FIG. 4, within the first reference plane, a third part of the second insulation layer 152 located on a bottom wall of the first reference groove has a midpoint X0 in the arrangement direction of the first reference sub-pixels and the second reference sub-pixels (the first direction X in an example of FIG. 4). A perpendicular line passing through the point X0 and perpendicular to the base substrate is L5, and the first reference protrusion close to the first reference groove has a highest point U1 away from the base substrate. An intersection point of the first reference protrusion close to the first reference groove and the fourth part of the third insulation layer is D1, an extension line passing through the point D1 along the arrangement direction of the first reference sub-pixel and the second reference sub-pixel has an intersection point X1 with L5, an intersection point close to the first reference groove between the extension line passing through the point D1 along the arrangement direction of the first reference sub-pixel and the second reference sub-pixel and the first reference protrusion close to the first reference groove is D2, and an intersection point of a perpendicular line from U1 to L5 is X2. Within the first reference plane, a side of the pixel opening of the first reference sub-pixel close to the base substrate and close to the first reference groove has a point O1, and an intersection point of a perpendicular line from the point O1 to L5 is X3. Point X0 and point D2, point X0 and point U1, point X0 and point D1, point X0 and point O1 define four virtual straight lines: L1, L2, L3 and L4, respectively. Angles between L1, L2, L3 and L4 with L5 are θ1, θ2, θ3 and θ9, respectively. A distance between X0 and D2 is l1, a distance between X0 and U1 is l2, a distance between X0 and D1 is l3, and a distance between X0 and O1 is l4. Within the first reference plane, a side of the pixel opening of the second reference sub-pixel close to the base substrate and close to the first reference groove has a point O2, the point X0 and the point O2 determines a dummy line 16, and a distance between the point X0 and the point O2 is l6.

In an example, it may be set as: l2*cos θ2>l1*cos θ1=l3*cos θ3, wherein a distance between point X0 and point U1 is l2, an included angle between L2 and L5 is θ2, a distance between point X0 and point D2 is l1, an included angle between L1 and L5 is θ1, a distance between point X0 and point D1 is l3, and an included angle between L3 and L5 is θ3. In this way, it is helpful to realize the partition structure to partition the charge generation layer and improve the cross-color problems.

In an example, it may be set as 14*cos θ9>l2*cos θ2, wherein a distance between point X0 and point O1 is l4, an included angle between L4 and L5 is θ9, a distance between point X0 and point U1 is l2, an included angle between L2 and L5 is θ2, and an orthographic projection of the pixel definition layer 171 on the base substrate 121 may include an orthographic projection of the protrusion of the partition structure (the first reference protrusion corresponds a position of the protrusion of the partition structure) and the groove on the base substrate, which helps to ensure the flatness of the part of the second anode 161 exposed by the pixel opening 172 and improve the optical display effect.

In an example, within the first reference plane, an intersection point of the first reference protrusion close to the first reference groove and a sixth part of the third insulation layer is closer to the base substrate than the point D2. That is, the sixth part of the third insulation layer 153 is closer to the base substrate than the fourth part of the third insulation layer 153, which is helpful to realize the partition structure to partition the charge generation layer and reduce the possibility of cross-color.

In an example, the bottom wall of the groove 142 is closer to the base substrate than a surface of the first anode 141 close to the base substrate, which is helpful to realize the partition structure to partition the charge generation layer and reduce the possibility of cross-color.

In an example, it may be set as:

0.8≤(l4*cos θ9−l2*cos θ2)/(l2*cos θ2−l3*cos θ3)≤1.2, wherein a distance between point X0 and point O1 is l4, an included angle between L4 and L5 is θ9, a distance between point X0 and point U1 is l2, an included angle between L2 and L5 is θ2, a distance between point X0 and point D1 is l3, and an included angle between L3 and L5 is θ3, which can ensure the flatness of the part of the second anode 161 exposed by the pixel opening 172 and the aperture ratio of the whole display substrate and improve the optical display effect on the premise of ensuring that the partition structure partitions the charge generating layer.

In an example, the light emitting wavelength of the first reference sub-pixel may be less than the light emitting wavelength of the second reference sub-pixel. For example, the first reference sub-pixel may be a green sub-pixel, the second reference sub-pixel may be a red sub-pixel. It may be set as 1.1≤l6/l4≤1.4, wherein a distance between point X0 and point O1 is l4, and a distance between point X0 and point O2 is l6. In this example, a thickness of the fourth insulation layer 154 of the second reference sub-pixel may be greater than a thickness of the fourth insulation layer 154 of the first reference sub-pixel. Thicknesses of the fourth insulation layers 154 of the sub-pixels of different colors may be different and the micro-cavity lengths of the sub-pixels of different colors may be adjusted by adjusting the thicknesses of the fourth insulation layers 154 of the sub-pixels of different colors. Among the sub-pixels of different colors, the longer the light emitting wavelength of the sub-pixel, the greater the thickness of the fourth insulation layer 154 of the sub-pixel may be.

In an example, it may be set as (l3*cos θ3)/(l4*cos θ9)≤0.72 and (l2*cos θ2)/(l4*cos θ9)≤0.81, wherein a distance between point X0 and point D1 is l3, an included angle between L3 and L5 is θ3, a distance between point X0 and point O1 is l4, an included angle between L4 and L5 is θ9, a distance between point X0 and point U1 is l2, and an included angle between L2 and L5 is θ2.

In some exemplary embodiments, FIG. 5 is a schematic top view of a partial structure of a display substrate according to an exemplary embodiment of the present disclosure. As shown in FIGS. 4 and 5, an arrangement direction of the first reference sub-pixel and the second reference sub-pixel is a first direction X, that is, the first reference sub-pixel and the second reference sub-pixel are adjacent in the first direction X. A straight line determined by the closest points between an orthographic projection of the first reference protrusion 311 on the base substrate and an orthographic projection of the second reference protrusion 312 on the base substrate is within the first reference plane. The multiple sub-pixels of the display area further includes a third reference sub-pixel adjacent to the first reference sub-pixels in a second direction Y, and a first protrusion provided on the third insulation layer at a periphery of a pixel opening of a third reference sub-pixel is used as a third reference protrusion 313.

In some exemplary embodiments, as shown in FIGS. 4 and 5, within the first reference plane, a first reference protrusion 311 close to the first reference groove has a highest point U1 away from the base substrate, the second reference protrusion 312 close to the first reference groove has a highest point U2 away from the base substrate, and a third part of the second insulation layer 152 on a bottom wall of the first reference groove has a midpoint X0 in the first direction X.

In some exemplary embodiments, as shown in FIGS. 4 and 5, a plane on which the base substrate is located is a projection plane, and an orthographic projection point of point U1 on the projection plane is U1″, and an orthographic projection point of point U2 on the projection plane is U2″. Within the projection plane, there is at least one intersection point between the straight line passing through the point U1″ and along the second direction Y and an orthographic projection of the third reference protrusion within the projection plane, an intersection point among the at least one intersection point closest to the point U1″ is point U3″, and the point U3″ is an orthographic projection point of the highest point U3 on the third reference protrusion away from the base substrate on the projection plane. A section passing through a straight line determined by the point U2″ and the point U3″ and perpendicular to the base substrate is used as a second reference plane, a section passing through a straight line determined by point U1″ and point U3″ and perpendicular to the base substrate is used as a third reference plane, a groove between the first anode of the second reference sub-pixel and the first anode of the third reference sub-pixel is used as a second reference groove, and a groove between the first anode of the first reference sub-pixel and the first anode of the third reference sub-pixel is used as a third reference groove. Within the second reference plane, a third part of the second insulation layer located on a bottom wall of the second reference groove has a midpoint Y0 in a direction parallel to a straight line determined by points U2″ and U3″. Within the third reference plane, a third part of the second insulation layer located on a bottom wall of the third reference groove has a midpoint Z in the second direction.

In some exemplary embodiments, as shown in FIGS. 4 and 5, taking a direction perpendicular to the base substrate as a third direction (consistent with a direction of the perpendicular line L5 described above), an included angle between a straight line determined by point Y0 and point U2 and the third direction is θ5, an included angle between a straight line determined by point Z and point U3 and the third direction is θ7, and an included angle between L2 and L5 is θ2, which may be set as θ5>θ2, θ5>θ7.

In some exemplary embodiments, as shown in FIGS. 4 and 5, an included angle between a straight line determined by point X0 and point U2 and the third direction is θ4, an included angle between a straight line determined by point Y0 and point U3 and the third direction is θ6, an included angle between a straight line determined by point Z and point U1 and the third direction is θ8, an included angle between a straight line determined by point Y0 and point U2 and the third direction is θ5, an included angle between a straight line determined by point Z and point U3 and the third direction is θ7, and an included angle between L2 and L5 is θ2, which may be set as θ2≈θ4, θ5≈θ6, θ7≈θ8. It can be understood that a difference between θ2 and θ4 is within 10°, a difference between θ5 and θ6 is within 10°, a difference between θ7 and θ8 is within 10°. For example, a difference between θ2 and θ4 can be within 5°, a difference between θ5 and θ6 can be within 5°, a difference between θ7 and θ8 can be within 5°.

In an example, the light emitting wavelength of the first reference sub-pixel may be less than the light emitting wavelength of the second reference sub-pixel, and the third reference sub-pixel and the first reference sub-pixel may emit light of the same color. For example, the third reference sub-pixel and the first reference sub-pixel may both emit green light, and the second reference sub-pixel may emit red light.

In some exemplary embodiments, the display area includes a first structural unit and a second structural unit, the first structural unit and the second structural unit both have θ1 to θ9, l1, l2, l3, l4, and point U1, point U2, point U3, point O1, point D1, point D2, midpoint X0, midpoint Y0, and midpoint Z described.

In some exemplary embodiments, a ratio of θ5 of the first structural unit to θ5 of the second structural unit is greater than a ratio of θ2 of the first structural unit to θ2 of the second structural unit. The ratio of θ5 of the first structural unit to θ5 of the second structural unit is greater than a ratio of θ7 of the first structural unit to θ7 of the second structural unit.

In some exemplary embodiments, a ratio of a distance between point U2 and point U3 of the second structural unit to a distance between point U2 and point U3 of the first structural unit is A1, a ratio of a distance between point U1 and point U2 of the second structural unit to a distance between point U1 and point U2 of the first structural unit is A2, and a ratio of a distance between point U1 and point U3 of the second structural unit to a distance between point U1 and point U3 of the first structural unit is A3, which may be set as A1<A2, A1<A3. In this way, it is helpful to improve the aperture ratio and achieve higher pixel density (PPI) on the premise of reducing cross-color.

In some exemplary embodiments, d1=l4*sin θ9 is defined. A d1 of the second structural unit may be less than a d1 of the first structural unit, wherein a distance between the point X0 and the point O1 is l4 and an included angle between L4 and L5 is θ9.

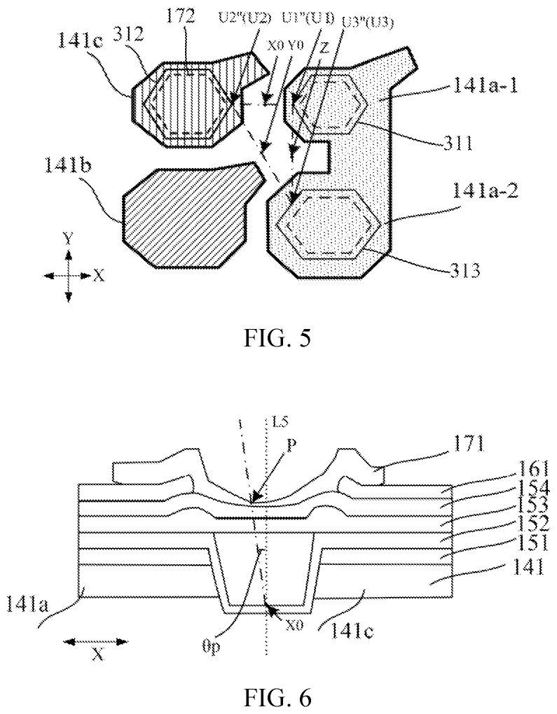

In some exemplary embodiments, FIG. 6 is a schematic diagram of another partial structure of FIG. 3. As shown in FIGS. 4 and 6, within the first reference plane, a surface of the pixel definition layer 171 located between the first reference sub-pixel and the second reference sub-pixel facing away from the base substrate has a lowest point P close to the base substrate in the direction perpendicular to the base substrate, and the point P is not located on the perpendicular line L5. Point P may be located on a side of the perpendicular line L5 on which the sub-pixel with a shorter light emitting wavelength among the first reference sub-pixel and the second reference sub-pixel is located. For example, in a case where one of the first reference sub-pixel and the second reference sub-pixel is a green sub-pixel and the other is a red sub-pixel, the point P is located on a side of the perpendicular line L5 on which the green sub-pixel is located (for example, in the example of FIG. 6, the left side is a green first reference sub-pixel, the right side is a red second reference sub-pixel, and the point P is located on a side of the perpendicular line L5 on which the left green sub-pixel is located). In a case where one of the first reference sub-pixel and the second reference sub-pixel is a green sub-pixel and the other is a blue sub-pixel, the point P is located on a side of the perpendicular line L5 on which the blue sub-pixel is located. In a case where one of the first reference sub-pixel and the second reference sub-pixel is a red sub-pixel and the other is a blue sub-pixel, the point P is located on a side of the perpendicular line L5 on which the blue sub-pixel is located.

In an example, within the first reference plane, an included angle between a straight line determined by point X0 and point P and the perpendicular line L5 is θp and an included angle between L1 and L5 is θ1, which may be set as θp<θ1. That is, the point P is closer to the perpendicular line L5 than the point D2.

In an example, a distance between point X0 and point P is lp, a distance between point X0 and point O1 is l4, an included angle between L4 and L5 is θ9, a distance between point X0 and point U1 is l2, an included angle between L2 and L5 is θ2, a distance between point X0 and point D1 is l3, and an included angle between L3 and L5 is θ3, which may be set as:

0.9<(lp*cos θp−l2*cos θ2)/(l2*cos θ2−l3*cos θ3)<1.1;

and(l2*cos θ2)/(l4*cos θ9)≤0.81.

At this point, point P may be closer to the base substrate than point O1, which is helpful for the partition structure to partition the charge generation layer.

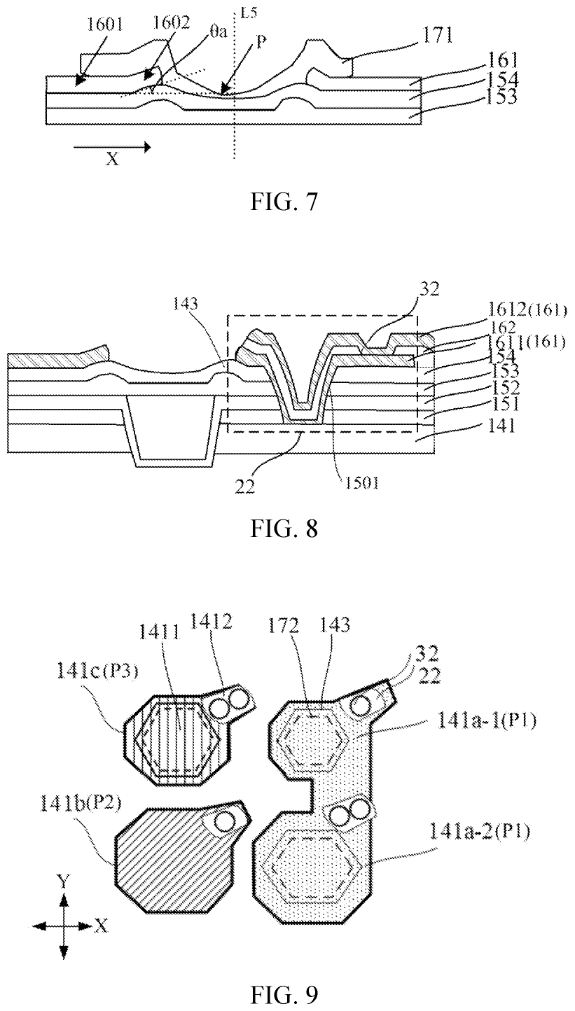

In some exemplary embodiments, FIG. 7 is a schematic diagram of yet another partial structure of FIG. 3. As shown in FIGS. 4 and 7, the second anode 161 includes a first part 1601 substantially parallel to the base substrate and a second part 1602 at an included angle with the base substrate, and the second part 1602 of the second anode 161 is closer to an edge of the second anode 161 than the first part 1601. An orthographic projection of the first part 1601 of the second anode 161 on the base substrate is not overlapped with an orthographic projection of the protrusion on the base substrate, an orthographic projection of the second part 1602 of the second anode 161 on the base substrate is overlapped with the orthographic projection of the protrusion on the base substrate, and the second part 1602 of the second anode 161 is located on the protrusion. This facilitates improving the aperture ratio of the display substrate and ensuring a flatness of the part of the second anode 161 exposed by the pixel opening.

In an example, an included angle between a straight line determined by point X0 and point P and the perpendicular line L5 is θp and an included angle between the second part 1602 of the second anode 161 and the base substrate (a plane on which the base substrate is located) is θa, which may be set as θp<θₐ<θ2. Included angles θ2 between the second parts 1602 of the second anodes 161 of the sub-pixels of different colors and the base substrate (the plane on which the base substrate is located) may be substantially the same.

In an example, a light emitting wavelength of the first reference sub-pixel may be less than a light emitting wavelength of the second reference sub-pixel, and within the first reference plane, a distance from the second anode of the first reference sub-pixel to the point P is less than a distance from the second anode of the second reference sub-pixel to the point P along an arrangement direction of the first reference sub-pixel and the second reference sub-pixel. For example, in the examples of FIGS. 4 and 7, the first reference sub-pixel (the left sub-pixel in FIG. 7) is a green sub-pixel, the second reference sub-pixel (the right sub-pixel in FIG. 7) is a red sub-pixel, and the arrangement direction of the first reference sub-pixel and the second reference sub-pixel is a first direction X. Within the first reference plane, a distance from the second anode 161 of the green sub-pixel to the point P is less than a distance from the second anode 161 of the red sub-pixel to the point P along the first direction X.

In an example, the light emitting wavelength of the first reference sub-pixel may be less than the light emitting wavelength of the second reference sub-pixel. The pixel definition layer 171 includes a first part overlapped with the second anode 161 of the first reference sub-pixel, and a second part overlapped with the second anode 161 of the second reference sub-pixel, and a surface of the first part of the pixel definition layer 171 facing away from the base substrate is closer to the base substrate than a surface of the second part of the pixel definition layer 171 facing away from the base substrate.

In some exemplary embodiments, FIG. 8 is a schematic sectional view of a partial structure of a display substrate according to an exemplary embodiment of the present disclosure. As shown in FIG. 8, a second anode 161 is disposed on a surface of an insulation layer 15 facing away from a base substrate. The second anode 161 may include a first sub-electrode 1611 and a second sub-electrode 1612 that are stacked sequentially along a direction away from the base substrate. A fifth insulation layer 162 may be disposed between the first sub-electrode 1611 and the second sub-electrode 1612, and the first sub-electrode 1611 and the second sub-electrode 1612 are overlapped through a second via 32 provided in the fifth insulation layer 162. The first sub-electrode 1611 is overlapped with the first anode 141 through a first via 1501 provided in the insulation layer 15. The first anode 141 and the second anode 161 have an equipotential. The dashed line box 22 shows an overlapping structure of the first sub-electrode 1611 and the second sub-electrode 1612 and an overlapping structure of the first sub-electrode 1611 and the first anode 141.

In an example, the first sub-electrode 1611 and the second sub-electrode 1612 may both be transparent conductive materials, such as indium tin oxide (ITO), indium zinc oxide (IZO), and the like.

In some exemplary embodiments, the first via 1501 and the second via 32 of at least one sub-pixel may be surrounded by one or more protrusions 143 on a periphery of a pixel opening of the sub-pixel. In an example, a shape of the protrusion(s) 143 may be substantially the same as a shape of the anode (or the first anode).

In some exemplary embodiments, FIG. 9 is a schematic top view of another partial structure of a display substrate according to an exemplary embodiment of the present disclosure. As shown in FIG. 9, a display area of the display substrate may include multiple pixel units arranged in an array, one pixel unit may include four sub-pixels, for example, one pixel unit may include two first sub-pixels P1, one second sub-pixel P2 and one third sub-pixel P3. Four sub-pixels in the pixel unit can be arranged in two rows and two columns and are substantially rectangular, two first sub-pixels P1 are located in the same column, and the second sub-pixel P2 and the third sub-pixel P3 are located in the same column. A row direction is a first direction X in FIG. 9 and a column direction is a second direction Y in FIG. 9. That is, in the pixel unit, one of the first sub-pixels P1 and the third sub-pixel P3 are located in the same row and arranged in the first direction X, the other first sub-pixel P1 and the second sub-pixel P2 are located in the same row and arranged in the first direction X, two first sub-pixels P1 are located in the same column and arranged in the second direction Y, and the second sub-pixel P2 and the third sub-pixel P3 are located in the same column and arranged in the second direction Y. The first direction X intersects with the second direction Y, for example, the first direction X and the second direction Y may be perpendicular to each other.

In some exemplary embodiments, as shown in FIG. 9, FIG. 9 illustrates a first anode 141a-1 of one of the first sub-pixels P1, a first anode 141a-2 of the other of the first sub-pixels P1, a first anode 141b of the second sub-pixel P2, and a first anode 141c of the third sub-pixel P3. The first anodes 141a-1 and 141a-2 of the two first sub-pixels P1 may be connected to be of an integral structure. In an example, the first sub-pixel P1 may emit green light, the second sub-pixel P2 may emit blue light, and the third sub-pixel P3 may emit red light.

In some exemplary embodiments, as shown in FIG. 9, an orthographic projection of a first anode 141 of the sub-pixel on a base substrate may include an orthographic projection of a second via 32 on the base substrate. In an example, the first anode 141 of the sub-pixel may include a main body part 1411 and a connection part 1412 connected to the main body part 1411, and an orthographic projection of the connection part 1412 on the base substrate is overlapped with an orthographic projection of the second via 32 on the base substrate.

In some exemplary embodiments, as shown in FIG. 9, a quantity of the second via(s) 32 in each sub-pixel in the pixel unit may be one or more, and different sub-pixels may have different quantities of second via 32.

In an example, sub-pixels of different colors located in the same row and arranged in the first direction X may have different quantities of the second via 32. All of the sub-pixels may have the same quantity of second via 32 in a direction at an angle of approximately 45 degrees with both the first direction X and the second direction Y. For example, in the pixel unit, a first sub-pixel P1 located in the same row as the third sub-pixel P3 may have one second via 32, a first sub-pixel P1 located in the same row as the second sub-pixel P2 may have two second vias 32, the second sub-pixel P2 may have one second via 32, and the third sub-pixel P3 may have two second vias 32. That is, in the pixel unit, a quantity of the second via(s) 32 of the first sub-pixel P1 located in the same row as the third sub-pixel P3 is the same as a quantity of the second via(s) 32 of the second sub-pixel P2, and a quantity of the second via(s) 32 of the first sub-pixel P1 located in the same row as the second sub-pixel P2 is the same as a quantity of the second via(s) 32 of the third sub-pixel P3. In this way, on one hand, the process stability can be improved to ensure the electrode overlap yield, and on the other hand, the aperture ratio of the display substrate can be improved.

In other implementations, all sub-pixels on the display substrate have the same quantity of second via(s) 32. For example, all sub-pixels on the display substrate each have one or two second vias 32.

In some exemplary embodiments, as shown in FIG. 9, one or more protrusions 143 are provided on a periphery of the pixel opening 172 of at least one sub-pixel, and the first via and the second via 32 of at least one sub-pixel may be located outside an area surrounded by the one or more protrusions 143 on the periphery of the pixel opening 172 of the sub-pixel. For example, one protrusion 143 is provided on the periphery of the pixel opening 172 of at least one sub-pixel, the protrusion 143 may be a closed or non-closed annular, a shape of the protrusion 143 may be approximately the same as a shape of the pixel opening 172 of the sub-pixel, and the first via and the second via 32 of the sub-pixel are located outside an area surrounded by the protrusion 143.

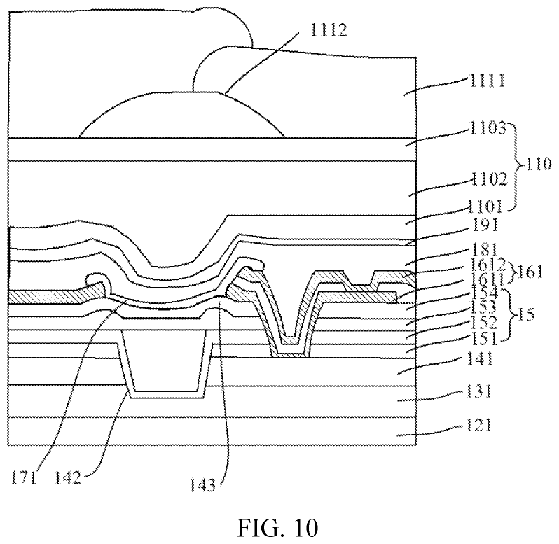

In some exemplary embodiments, FIG. 10 is a schematic sectional view of another partial structure of a display substrate according to some exemplary embodiments. As shown in FIG. 10, in a direction perpendicular to a base substrate, the display substrate includes a drive structure layer, a light emitting structure layer, and an encapsulation structure layer 110 that are stacked sequentially on the base substrate, and a color filter layer 1111 and a black matrix 1112 disposed on a side of the encapsulation structure layer 110 facing away from the base substrate.

In an example, the encapsulation structure layer 110 may be disposed on a surface of a cathode layer of the light emitting structure layer facing away from the base substrate. The encapsulation structure layer 110 may include a first encapsulation layer 1101, a second encapsulation layer 1102, and a third encapsulation layer 1103 that are stacked sequentially in a direction away from the base substrate. A main material (a material with a largest composition in a film layer) of the first encapsulation layer 1101 and the third encapsulation layer 1103 may be an inorganic material, and a main material of the second encapsulation layer 1102 may be an organic material, thus facilitating encapsulation and avoiding erosion by water vapor.

In an example, the main material of the first encapsulation layer 1101 and the third encapsulation layer 1103 may be silicon oxynitride with a refractive index of 1.75 to 1.8. A thickness of the first encapsulation layer 1101 may be 200 nm to 500 nm and a thickness of the third encapsulation layer 1103 may be 850 nm to 1000 nm. Each of the first encapsulation layer 1101 and the third encapsulation layer 1103 may be a single film layer or multiple inorganic material film layers that are stacked. The main material of the second encapsulation layer 1102 may be an epoxy resin with a refractive index of 1.54.

In an example, a thickness of the second encapsulation layer 1102 of a first sub-pixel area and a thickness of the second encapsulation layer 1102 of a third sub-pixel area may be approximately the same and may be about 2 microns to 2.6 microns. A thickness of the second encapsulation layer 1102 of a second sub-pixel area may be greater than the thickness of the second encapsulation layer 1102 of the first sub-pixel area and the third sub-pixel area.

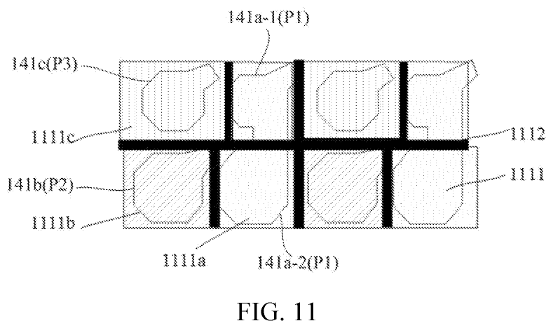

In an example, FIG. 11 is a schematic diagram of a partial planar structure of a display substrate according to some exemplary embodiments. As shown in FIGS. 10 and 11, the color filter layer 1111 includes multiple filter units, and the multiple filter units include multiple first filter units 1111a located within a first sub-pixel area and capable of filtering out first color light, multiple second filter units 1111b located within a second sub-pixel area and capable of filtering out second color light, and multiple third filter units 1111c located within a third sub-pixel area and capable of filtering out third color light. The black matrix 1112 is provided with multiple light transmitting openings and each filter unit of the color filter layer 1111 is provided within a corresponding light transmitting opening to filter the light emitted from a corresponding sub-pixel and realize the full-color display. The black matrix 1112 may prevent cross-color between sub-pixels.

In an example, the first filter unit 1111a is configured to transmit a green light wave with a center wavelength of 540 nm, the second filter unit 1111b is configured to transmit a blue light wave with a center wavelength of 470 nm, and the third filter unit 1111c is configured to transmit a red light wave with a center wavelength of 610 nm.

In an example, as shown in FIG. 10, an orthographic projection of the black matrix 1112 on the base substrate is overlapped with an orthographic projection of a groove 142 of a partition structure on the base substrate. At least two adjacent filter units may overlap and an overlapping part of the adjacent filter units may be located on the black matrix 1112, which may prevent cross-color between sub-pixels.

In an example, the filter units of adjacent sub-pixels of different colors have an overlapping, an overlapping part of the filter units of adjacent sub-pixels of different colors may be used as a black matrix, and a black matrix film layer may no longer be separately provided, which helps to simplify the process. For example, an overlapping part of the third filter unit and the first filter unit may be used as a black matrix between adjacent third sub-pixel and first sub-pixel.

In an example, the second encapsulation layer 1102 has certain leveling properties during the fabrication process, so that a surface of the second encapsulation layer 1102 facing away from the base substrate and a surface of the third encapsulation layer 1103 disposed on the second encapsulation layer 1102 facing away from the base substrate may both be planar surfaces. The color filter layer 1111 and the black matrix 1112 may act as a down-reflection layer and are disposed on a surface of the third encapsulation layer 1103 facing away from the base substrate.

In some exemplary embodiments, as shown in FIG. 11, FIG. 11 illustrates two pixel units and the sub-pixel arrangement of the pixel unit in the example of FIG. 11 may be the same as the sub-pixel arrangement of the pixel unit of FIG. 2 above.

In an example, the black matrix 1112 may be a grid-like structure and each grid aperture is one light transmitting opening. An orthographic projection of the light transmitting opening of the black matrix 1112 on the base substrate includes an orthographic projection of the pixel opening of the pixel definition layer on the base substrate. One light transmitting opening corresponds to a pixel opening of one corresponding sub-pixel. There may be a black matrix 1112 between two adjacent first sub-pixels.

In an example, a thickness of the first filter unit 1111a may be less than a thickness of the second filter unit 1111b and may be less than a thickness of the third filter unit 1111c.

In an example, a part of the third filter unit 1111c overlapping the first filter unit 1111a may be located on a side of the first filter unit 1111a facing away from the base substrate and a part of the first filter unit 1111a may be located on a side of the black matrix 1112 facing away from the base substrate.

In an example, a part of the third filter unit 1111c overlapping the second filter unit 1111b may be located on a side of the second filter unit 1111b facing away from the base substrate and a part of the second filter unit 1111b overlapping the first filter unit 1111a may be located on a side of the first filter unit 1111a facing away from the base substrate.

In an example, in an orthographic projection of the third filter unit 1111c on the base substrate, an area of a part that is not overlapped with an orthographic projection of the first anode 141c of the third sub-pixel on the base substrate is S1, in an orthographic projection of the first filter unit 1111a on the base substrate, an area of a part that is not overlapped with an orthographic projection of the first anode 141a of the first sub-pixel on the base substrate is S2, and in an orthographic projection of the second filter unit 1111b on the base substrate, an area of a part that is not overlapped with an orthographic projection of the first anode 141b of the second sub-pixel on the base substrate is S3. It may be set as S1>S2, or it may be set as S1>S3, or it may be set as S1>S2 and S1>S3, which helps adjust the hue.

In an example, the light emitting element of the display substrate may be provided to emit white light. The second filter unit 1111b may be provided with a light transmitting aperture and the white light emitted by the light emitting element of the second sub-pixel may be emitted through the light transmitting aperture on the second filter unit 1111b, thus improving the light output brightness of the display substrate.

An embodiment of the present disclosure further provides a display device, which includes the display substrate according to any one of the previous embodiments. The display device may be a near eye display device, for example, helmet-mounted displays, Augmented Reality (AR) glasses, Virtual Reality (VR) all-in-one machines and so on. Alternatively, the display device may be any product or component with a display function such as a mobile phone, a tablet computer, a television, a display, a laptop computer, a digital photo frame, or a navigator.

In the drawings, a size of a constituent element, and a thickness of a layer or a region are sometimes exaggerated for clarity. Therefore, an implementation of the present disclosure is not necessarily limited to the size, and a shape and size of each component in the drawings do not reflect an actual scale. In addition, the drawings schematically illustrate some examples, and an implementation of the present disclosure is not limited to the shapes or numerical values shown in the drawings.

In the description herein, “parallel” refers to a state in which an angle formed by two straight lines is above −10° and below 10°, and thus includes a state in which the angle is above−5° and below 5°. In addition, “perpendicular” refers to a state in which an angle formed by two straight lines is above 80° and below 100°, and thus includes a state in which the angle is above 85° and below 95°.

Ordinal numerals such as “first”, “second”, and “third” herein are set to avoid confusion between constituent elements, but are not intended to limit in terms of quantity.

Triangle, rectangle, trapezoid, pentagon, hexagon, etc. in the description herein are not strictly defined, and they may be approximate triangle, rectangle, trapezoid, pentagon, hexagon, etc. There may be some small deformations caused by tolerance, and there may be chamfer, arc edge, deformation, etc.

“About”, “roughly”, “substantially”, “approximate”, etc. used in the description herein refers to that a boundary is not defined strictly and a case within a process and measurement error range is allowed. For example, in the present disclosure, “substantially the same” may refer to a case where values differ by less than 10%.

In the description herein, orientation or position relationships indicated by the terms such as “upper”, “lower”, “left”, “right”, “top”, “inside”, “outside”, “axial”, “four corners” and the like are orientation or position relationships shown in the drawings, and are intended to facilitate description of the embodiments of the present disclosure and simplification of the description, but not to indicate or imply that the mentioned structure has a specific orientation or is constructed and operated in a specific orientation, therefore, it should not be understood as limitations on the present disclosure.

In the description herein, unless otherwise specified and defined explicitly, terms “connection”, “fixed connection”, “installation”, and “assembly” should be understood in a broad sense, and, for example, may be a fixed connection, a detachable connection, or an integrated connection; terms “installation”, “connection”, and “fixed connection” may be a direct connection, an indirect connection through an intermediary, or communication inside two elements. For those ordinarily skilled in the art, meanings of the above terms in the embodiments of the present disclosure may be understood according to situations.

1. A display substrate, comprising: a plurality of sub-pixels disposed on a base substrate, wherein the plurality of sub-pixels comprise a first sub-pixel emitting a first color light, a second sub-pixel emitting a second color light and a third sub-pixel emitting a third color light; the sub-pixels each comprise a light emitting element;
the display substrate comprises a drive structure layer and a light emitting structure layer that are stacked sequentially on the base substrate; the light emitting structure layer comprises an anode layer, a pixel definition layer, a light emitting functional layer and a cathode layer that are disposed sequentially in a direction away from the base substrate; the anode layer comprises a plurality of anodes, the pixel definition layer is disposed on a side of the plurality of anodes facing away from the base substrate and is provided with a plurality of pixel openings, the pixel openings expose the anodes, the light emitting functional layer and the cathode layer are stacked sequentially on the side of the anodes facing away from the base substrate; the pixel openings define the sub-pixels, and the light emitting element comprises the anodes, the light emitting functional layer, and the cathode layer;
the display substrate further comprises a partition structure, the partition structure comprises a groove located between adjacent anodes and a protrusion located between adjacent pixel openings.

2. The display substrate according to claim 1, wherein the anode layer comprises a first anode layer and a second anode layer that are disposed sequentially in the direction away from the base substrate, and the light emitting structure layer further comprises an insulation layer disposed between the first anode layer and the second anode layer;
the first anode layer comprises a plurality of first anodes, the second anode layer comprises a plurality of second anodes, and the second anodes are connected with the first anodes through a first via provided in the insulation layer; the anodes comprises the first anodes and the second anodes connected through the first via, the pixel definition layer is disposed at a side of the plurality of second anodes and the insulation layer facing away from the base substrate, and the pixel openings expose the second anodes; the light emitting functional layer and the cathode layer are stacked sequentially on a side of the second anodes facing away from the base substrate;
the groove is provided on a surface of the drive structure layer facing away from the base substrate, and the protrusion is provided on a surface of the insulation layer facing away from the base substrate; or
wherein in a direction parallel to the base substrate, the groove is further located between adjacent protrusions.

3. (canceled)

4. The display substrate according to claim 2, wherein an orthographic projection of the protrusion on the base substrate is overlapped with an orthographic projection of the first anodes on the base substrate.

5. The display substrate according to claim 2, wherein the second anodes are disposed on a surface of the insulation layer facing away from the base substrate, and a part of the second anodes close to an edge is located on the protrusion.

6. The display substrate according to claim 1, wherein an orthographic projection of the pixel definition layer on the base substrate comprises an orthographic projection of the protrusion on the base substrate.

7. (canceled)

8. The display substrate according to claim 2, wherein the thicknesses of the insulation layers are different for sub-pixels of different colors; or
wherein the insulation layer comprises a plurality of film layers that are stacked, and at least one film layer of the insulation layer is discontinuous between the pixel openings of sub-pixels of different colors;
wherein at least one film layer of the insulation layer close to the base substrate is discontinuous between the pixel openings of the sub-pixels of different colors and is not disposed in the groove, and at least one film layer of the insulation layer away from the base substrate is continuous between the pixel openings of the sub-pixels of different colors; and
wherein a film layer of the insulation layer close to the base substrate comprises a plurality of insulation sub-layers, each of the insulation sub-layers is disposed on a side of a corresponding one of the first anodes facing away from the base substrate, and an orthographic projection of the first anodes on the base substrate comprises an orthographic projection of the insulation sub-layers on the base substrate.

9-12. (canceled)

13. The display substrate according to claim 2, wherein the insulation layer comprises a plurality of film layers that are stacked, the light emitting structure layer further comprises a filling layer disposed in the groove, and the protrusion is provided on a film layer of the insulation layer located on a side of the filling layer facing away from the base substrate.

14. The display substrate according to claim 13, wherein the insulation layer comprises a second insulation layer and a third insulation layer that are stacked sequentially in the direction away from the base substrate;
the second insulation layer is disposed on a side of the plurality of first anodes facing away from the base substrate and disposed in the groove, the second insulation layer comprises a first part on the side of the first anodes facing away from the base substrate, a third part on a bottom wall of the groove, and a second part connecting the first part and the third part; the second part and the third part of the second insulation layer are recessed toward a side close to the base substrate compared to the first part and form a recessed part;
the filling layer is disposed on a surface of the second insulation layer facing away from the base substrate and in the recessed part of the second insulation layer;
the third insulation layer is disposed on a surface of the second insulation layer and the filling layer facing away from the base substrate, the third insulation layer comprises a fourth part on the first part of the second insulation layer, a sixth part on the filling layer, and a first protrusion connecting the fourth part and the sixth part;
the first protrusion is the protrusion of the partition structure; or, the insulation layer further comprises a fourth insulation layer disposed on a surface of the third insulation layer facing away from the base substrate, a second protrusion is formed at a position of the fourth insulation layer corresponding to the first protrusion, and the second protrusion is the protrusion of the partition structure.

15. The display substrate according to claim 14, wherein the insulation layer further comprises a first insulation layer disposed between the plurality of first anodes and the second insulation layer, the first insulation layer comprises a plurality of insulation sub-layers, and each of the insulation sub-layers is disposed between a corresponding one of the first anodes and the second insulation layer.

16-17. (canceled)

18. The display substrate according to claim 14, wherein the plurality of sub-pixels comprise a first reference sub-pixel and a second reference sub-pixel that are adjacent, the groove between a first anode of the first reference sub-pixel and a first anode of the second reference sub-pixel is used as a first reference groove, the first protrusion provided on the third insulation layer and at a periphery of a pixel opening of the first reference sub-pixel is used as a first reference protrusion, and the first protrusion provided on the third insulation layer and at a periphery of a pixel opening of the second reference sub-pixel is used as a second reference protrusion; a section parallel to an arrangement direction of the first reference sub-pixel and the second reference sub-pixel and perpendicular to the base substrate is used as a first reference plane;
within the first reference plane, a third part of the second insulation layer located on a bottom wall of the first reference groove has a midpoint X0 in the arrangement direction of the first reference sub-pixel and the second reference sub-pixel, a perpendicular line passing through X0 and perpendicular to the base substrate is L5, the first reference protrusion close to the first reference groove has a highest point U1 away from the base substrate, an intersection point of the first reference protrusion close to the first reference groove and the fourth part of the third insulation layer is D1, an extension line passing through D1 and along the arrangement direction of the first reference sub-pixel and the second reference sub-pixel has an intersection point X1 with L5, an intersection point close to the first reference groove between the extension line passing through D1 and along the arrangement direction of the first reference sub-pixel and the second reference sub-pixel and the first reference protrusion close to the first reference groove is D2, and an intersection point of a perpendicular line from U1 to L5 is X2; within the first reference plane, a side of the pixel opening of the first reference sub-pixel close to the base substrate and close to the first reference groove has a point O1, an intersection point of a perpendicular line from O1 to L5 is X3, point X0 and point D2, point X0 and point U1, point X0 and point D1, point X0 and point O1 respectively define four virtual straight lines: L1, L2, L3 and L4, and included angles between L1, L2, L3, L4 and L5 are θ1, θ2, θ3 and θ9 respectively; a distance between point X0 and point D2 is l1, a distance between point X0 and point U1 is l2, a distance between point X0 and point D1 is l3, and a distance between point X0 and point O1 is l4;
$$wherein 12 * cos θ2 > 11 * cos θ1 = 13 * cos θ3 ;$$
$$wherein 14 * cos θ9 > 12 * cos θ2 ;$$
$$wherein 0. 8 \leq ( 14 * cos θ9 - 12 * cos θ2 ) / ( 12 * cos θ2 - 13 * cos θ3 ) \leq 1.2 ;$$
$$wherein ( 13 * cos θ3 ) / ( 14 * cos θ9 ) \leq 0.72 ; and$$
$$wherein ( 12 * cos θ2 ) / ( 14 * cos θ9 ) \leq 0.81 .$$

19-22. (canceled)

23. The display substrate according to claim 18, wherein within the first reference plane, a side of the pixel opening of the second reference sub-pixel close to the base substrate and close to the first reference groove has a point O2, point X0 and point O2 determine a dummy line L6, and a distance between point X0 and point O2 is l6; a light emitting wavelength of the first reference sub-pixel is less than a light emitting wavelength of the second reference sub-pixel, 1.1<l6/l4≤1.4.

24. The display substrate according to claim 18, wherein within the first reference plane, an intersection point of the first reference protrusion close to the first reference groove and the sixth part of the third insulation layer is closer to the base substrate than point D2.

25. The display substrate according to claim 18, wherein the first reference sub-pixel and the second reference sub-pixel are adjacent in a first direction, and a straight line determined by the closest points between an orthographic projection of the first reference protrusion on the base substrate and an orthographic projection of the second reference protrusion on the base substrate is within the first reference plane;
the plurality of sub-pixels further comprise a third reference sub-pixel adjacent to the first reference sub-pixel in a second direction, and the first protrusion provided on the third insulation layer and at a periphery of a pixel opening of the third reference sub-pixel is used as a third reference protrusion;
within the first reference plane, the second reference protrusion close to the first reference groove has a highest point U2 away from the base substrate;
a plane on which the base substrate is located is a projection plane, an orthographic projection point of point U1 on the projection plane is U1″, and an orthographic projection point of point U2 on the projection plane is U2″; within the projection plane, there is at least one intersection point between a straight line passing through the point U1″ and along the second direction and an orthographic projection of the third reference protrusion within the projection plane, an intersection point in the at least one intersection point closest to the point U1″ is point U3″, and the point U3″ is an orthographic projection point of the highest point U3 on the third reference protrusion away from the base substrate on the projection plane; a section passing through a straight line determined by point U2″ and point U3″ and perpendicular to the base substrate is used as a second reference plane, a section passing through a straight line determined by point U1″ and point U3″ and perpendicular to the base substrate is used as a third reference plane, a groove between a first anode of the second reference sub-pixel and a first anode of the third reference sub-pixel is used as a second reference groove, and a groove between a first anode of the first reference sub-pixel and the first anode of the third reference sub-pixel is used as a third reference groove; within the second reference plane, a third part of the second insulation layer located on a bottom wall of the second reference groove has a midpoint Y0 in a direction parallel to the straight line determined by points U2″ and U3″; within the third reference plane, a third part of the second insulation layer located on a bottom wall of the third reference groove has a midpoint Z in the second direction;
a direction perpendicular to the base substrate is used as a third direction, an included angle between a straight line determined by point Y0 and point U2 and the third direction is θ5, and an included angle between a straight line determined by point Z and point U3 and the third direction is θ7, wherein θ5>θ2, and θ5>θ7;
wherein an included angle between a straight line determined by point X0 and point U2 and the third direction is θ4, an included angle between a straight line determined by point Y0 and point U3 and the third direction is θ6, and an included angle between a straight line determined by point Z and point U1 and the third direction is θ8, wherein a difference between θ2 and θ4 is within 10°, a difference between θ5 and θ6 is within 10°, and a difference between θ7 and θ8 is within 10°; and
wherein a light emitting wavelength of the first reference sub-pixel is less than a light emitting wavelength of the second reference sub-pixel, and the third reference sub-pixel and the first reference sub-pixel emit light of the same color.

26-36. (canceled)

37. The display substrate according to claim 2, wherein the second anodes are disposed on a surface of the insulation layer facing away from the base substrate, the second anodes comprise a first sub-electrode and a second sub-electrode that are stacked sequentially in the direction away from the base substrate, a fifth insulation layer is disposed between the first sub-electrode and the second sub-electrode, and the first sub-electrode and the second sub-electrode are connected through a second via provided in the fifth insulation layer; the first sub-electrode is connected with the first anodes through the first via; and
wherein an orthographic projection of the first anodes on the base substrate comprises an orthographic projection of the second via on the base substrate.

38. (canceled)

39. The display substrate according to claim 37, wherein a quantity of second vias in the sub-pixels is one or more.

40. The display substrate according to claim 37, wherein the display substrate comprises a plurality of pixel units arranged in an array, and a pixel unit comprises two first sub-pixels, one second sub-pixel and one third sub-pixel;
in the pixel unit, one of the first sub-pixels and the third sub-pixel are located in the same row and arranged along a first direction, the other of the first sub-pixels and the second sub-pixel are located in the same row and arranged along the first direction, the two first sub-pixels are located in the same column and arranged along a second direction, and the second sub-pixel and the third sub-pixel are located in the same column and arranged along the second direction, the first direction intersects with the second direction;
in the pixel unit, a quantity of second vias of the first sub-pixel located in the same row as the third sub-pixel is the same as a quantity of second vias of the second sub-pixel, and a quantity of second vias of the first sub-pixel located in the same row as the second sub-pixel is the same as a quantity of second vias of the third sub-pixel.

41. The display substrate according to claim 1, further comprising: an encapsulation structure layer disposed on a side of the light emitting structure layer facing away from the base substrate, wherein the encapsulation structure layer comprises a first encapsulation layer, a second encapsulation layer, and a third encapsulation layer that are stacked sequentially in the direction away from the base substrate; a main material of the first encapsulation layer and the third encapsulation layer is an inorganic material, and a main material of the second encapsulation layer is an organic material;
a light emitting wavelength of the second sub-pixel is less than a light emitting wavelength of the first sub-pixel, a light emitting wavelength of the first sub-pixel is less than a light emitting wavelength of the third sub-pixel, and a thickness of the second encapsulation layer of a second sub-pixel area is greater than a thickness of the second encapsulation layer of a first sub-pixel area and a third sub-pixel area.

42. The display substrate according to claim 1, further comprising: an encapsulation structure layer disposed on a side of the light emitting structure layer facing away from the base substrate; and a color filter layer and a black matrix disposed on a side of the encapsulation structure layer facing away from the base substrate;
wherein the color filter layer comprises a plurality of filter units, the plurality of filter units comprise a plurality of first filter units located in a first sub-pixel area and capable of filtering out the first color light, a plurality of second filter units located in a second sub-pixel area and capable of filtering out the second color light, and a plurality of third filter units located in a third sub-pixel area and capable of filtering out the third color light;
the black matrix is provided with a plurality of light transmitting openings, and the filter units are provided in the light transmitting openings; an orthographic projection of the black matrix on the base substrate is overlapped with an orthographic projection of the groove of the partition structure on the base substrate.

43. The display substrate according to claim 42, wherein at least two adjacent filter units are overlapped, and an overlapping part of the adjacent filter units is located on the black matrix.

44-51. (canceled)

52. A display device, comprising a display substrate according to claim 1.
